(19) United States
(12) Patent Application Publication
(10) Pub. No.: US 2008/0198277 A1
(43) Pub. Date: Aug. 21, 2008

(54) Indicator of Presence of Ac Voltage

(76) Inventors: Jan Czyzewski, Krakow (PL); Robert Huber, Ketsch (DE); Mariusz Luto, Bialystok (PL)

Correspondence Address: Paul R Katterle;ABB, Legal Dept-4U6, 29801 Euclid Avenue, Wickliffe, OH, 44092-1832, US

(21) Appl. No.: 11/659,631

(22) PCT Filed: Aug. 4, 2005
(86) PCT No.: PCT/PL05/00046

§ 371 Date: Oct. 22, 2007

(30) Foreign Application Priority Data
Aug. 18, 2004 (PL) P 369639

(51) Int. Cl. G01R 19/155; G02F 1/13

(52) U.S. Cl. 349/1; 324/133

(57) ABSTRACT

The subject of the invention is an indicator of presence of AC voltage in medium or high voltage conductors and/or conducting elements of transmission and distribution systems, whose basic AC voltage detecting and indicating element is a liquid crystal display (1). The indicator according to the invention is characterized in that its housing (8) has the shape of a frame closed by a transparent plate (9) on the front and by a conducting element (10) on the back. At least one row of circumferential ribs (11) is positioned around the frame window. The liquid crystal display (1) is placed hermetically between the transparent plate (9) of the frame window and the conducting element (10) and it has electrodes in the form of conducting segments. One of the conducting segments (3) is the current-collecting electrode of the indicator, and another of the conducting segments (3) has a conducting terminal (12) connected to it, which terminal is connected with the conducting element of the indicator (10) by a connector (23), and which terminal is connected through a resistive element (13), with a terminal (7) connected to the current-collecting electrode.

The subject of he invention is an indicator of alternating-current (AC) voltage in conductors and/or conducting components of medium or high voltage transmission and distribution systems, whose basic AC voltage detecting and indicating element is a liquid crystal display (LCD). The indicator is attached to the surface of the tested conductor or conducting component or is placed close to them.

There are known various types of indicators of voltage presence provided with LCDs, which are not supplied from an external current source. Such indicators contain at least one current-collecting electrode which typically has the shape of a flat plate. An indicator of this type is placed on the tested conductor in such way that the current-collecting electrode is positioned basically parallel to the equipotential surfaces of the electric field generated around the tested conductor. The surface area of the current-collecting electrode is adjusted so as to ensure that the capacitive current flowing from it to the earthed environment of the tested conductor or, in the case of three-phase systems, to another phase conductor, is sufficient to cause a change the optical state of the display and to display a pattern, sign, inscription, or to change its color. Such capacitive current has a very small value, for example, if the indicator is installed on a conducting element of a typical air-insulated equipment, then the capacitive current is not more than 10-100 nA/cm² per unit of the current-collecting electrode area. Therefore the indicator must have a very high impedance, so that with such low capacitive current values a voltage drop sufficient to change the state of the optical indicator can be obtained.

An indicator for indicating live conductors which incorporates an LCD is known from patent description U.S. Pat. No. 5,274,324. This indicator consists of a closed, cuboidal housing made of an insulating material, whose front wall is provided with a transparent window in which a high-impedance display is placed, for instance a liquid crystal display, for indicating the presence of voltage. A conducting element in the form of a probe for testing voltage in conductors by connecting the probe to the conductor is attached to the back housing wall. A coupling element in the form of a metal plate which is electrically connected to one of the LCD electrodes is placed in the housing. The coupling element has the function of the capacitive-current collecting electrode. The other display electrode is connected to the probe through a resistive element. Both display electrodes are coupled with one another by means of a resistive element used to discharge the display. The indicator can also be furnished with an electric circuit for testing the indicator functionality.

A published application WO 2004/023151 describes a voltage indicator that uses a liquid-crystal, electrophoretic or electrochromic display. The indicator according to this solution consists of electrodes in the form of two external conducting layers of which at least on layer is transparent, an intermediate layer of a structure showing electro-optical properties placed between the electrodes, and a dielectric layer placed between the surface of one of the electrodes and the intermediate layer from which it is separated by an additional conducting layer. The electrodes are electrically connected with one another by means of a diode. The transparent electrode of the indicator is its current-collecting electrode. One of exemplary embodiments of the invention reveals a solution in which the additional conducting layer is connected with one of the other conducting layers by means of a resistive element. The purpose of this element is the regulation of the mutual proportion of the real and the imaginary parts of the impedances of the intermediate and the dielectric layers, which enables a suitable division of the DC and the AC voltage components among these layers and allows to obtain the maximum sensitivity of the indicator.

A liquid crystal display for detecting live conductors by using the threshold voltage of the LCD is know from a Japanese patent application No. 61-003069. A known two-electrode LCD is provided with two additional electrodes of which one is attached to the front wall of the display and the other to its back wall. Both electrodes of the LCD are electrically connected with the additional electrodes, so that each additional electrode is connected with a different electrode of the LCD. In this solution the additional electrode attached to the front wall of the display is the current-collecting electrode.

Another LCD for indicating voltage is known from a published Japanese description No. 63-044173. Like the device presented in description JP 61-003069, this device incorporates a liquid crystal display and two additional electrodes of which one is galvanically connected with one sign electrode of the display and the other, which is transparent, is placed directly on the display surface and thus it is capacitively coupled with the other, common electrode of the display. In this solution, the transparent additional electrode is the current-collecting electrode of the indicator.

A high reliability and adequate durability are required from a voltage indicator used to indicate voltage in medium and high voltage conductors and equipment, especially ones located outdoors and exposed to harmful action of diverse weather conditions. Air-insulated electric equipment often operates for periods of 20 to 30 years. Such equipment operates usually maintenance free. For that reason, voltage indicators in such equipment or its components are required not only to be highly durable but also to ensure fault-free operation for an adequately long time.

Known indicators incorporating liquid crystal displays are fairly durable. However, during their operation in various climatic conditions and when they are located outdoors, their durability may turn out to be insufficient for their commercial use. Adverse climatic conditions, such as high humidity, precipitation or brine mist, can cause dampness of the indicator surface, which in turn reduces the resistance of the indicator to external short-cuts. A reduction in such resistance, with high impedance of the LCD required to obtain a satisfactory sensitivity of the indicator, can lead to the loss of its functionality.

Another cause of reduced durability of an indicator incorporating an LCD is its comparatively small resistance to the accumulation of static charges on its external elements. Such charges, gathering uncontrollably on the surfaces of medium and high voltage transmission and distribution equipment, can produce DC component of voltage in the liquid crystal elements of the indicator, which considerably reduces their life.

The essence of the indicator of presence of AC voltage, according to the invention, comprising a liquid crystal display in an insulating housing, the indications of which display are read in a window in the front wall of the housing, and which display is electrically connected with a conducting element used to couple the display with the examined object, is that the housing of the indicator has the shape of a frame and it is made of a material with strongly hydrophobic surface, which frame on the front side is closed by a transparent plate placed in the frame window, and on the back side it is closed by a conducting element, while at least one row of circumferential ribs is positioned around the frame window, and the liquid crystal display is hermetically placed between the transparent plate of the frame window and the conducting element, and it has electrodes in the form of conducting segments, where one of the conducting segments with the largest surface area is the current-collecting electrode of the indicator, and to another of the conducting segments there is connected a conducting terminal which is connected to the conducting element of the indicator by means of a connector and which is connected through a resistive element to a terminal attached to the current-collecting electrode.

In another variant of the invention, the liquid crystal display is placed hermetically between the transparent plate of the frame window and a dielectric plate adjacent to the conducting element which closes the housing frame on its back part.

The dielectric plate is preferably made of glass.

Alternatively the dielectric plate is made of a thermoplastic polymer.

In both variants of the invention the transparent plate is preferably made of glass.

In both variants of the invention the circumferential ribs preferably stand out above the housing window level.

In both variants of the invention the housing frame is preferably made of a silicone elastomer with permanently hydrophobic surface.

In both variants of the invention the housing frame is alternatively made of a thermoplastic polymer coated by a thin layer of hydrophobic surface properties.

In both variants of the invention the resistive element is preferably made of a thermoplastic polymer having anti-electrostatic properties.

In both variants of the invention the resistive element is alternatively deposited on one of the substrate plates of the liquid crystal display between its terminals in the form of a resistive paint.

In both variants of the invention the resistive element has alternatively the form of a plate with a resistive layer applied onto it.

In both variants of the invention the resistive element is alternatively a layer of resistive material glued to the indicator terminals with a conductive glue.

In both variants of the invention the resistive element is preferably made of resistive paper, fabric or foil.

In both variants of the invention the conductive element is preferably made of a thermoplastic polymer with a conductive admixture in the form of carbon particles, conducting polymer or metallic fibers.

In both variants of the invention the conductive element is alternatively made of a silicone elastomer with a conductive admixture.

In both variants of the invention the conductive element is alternatively made of a silicone elastomer with a metallic or polymer core.

An advantage of the indicator according to the invention is its simple design and comparatively small dimensions. The indicator can be used for indicating voltage presence in medium voltage unscreened wires or equipment after attaching it to insulated or non insulated wires. Indication is done by displaying a sign, which can be read on the indicator display with unaided eye from a considerable distance. The indicator is suitable for operation in diverse ambient conditions, can be manufactured using simple manufacturing methods and is very durable and reliable.

The subject of the invention is shown as an embodiment example on the drawing where

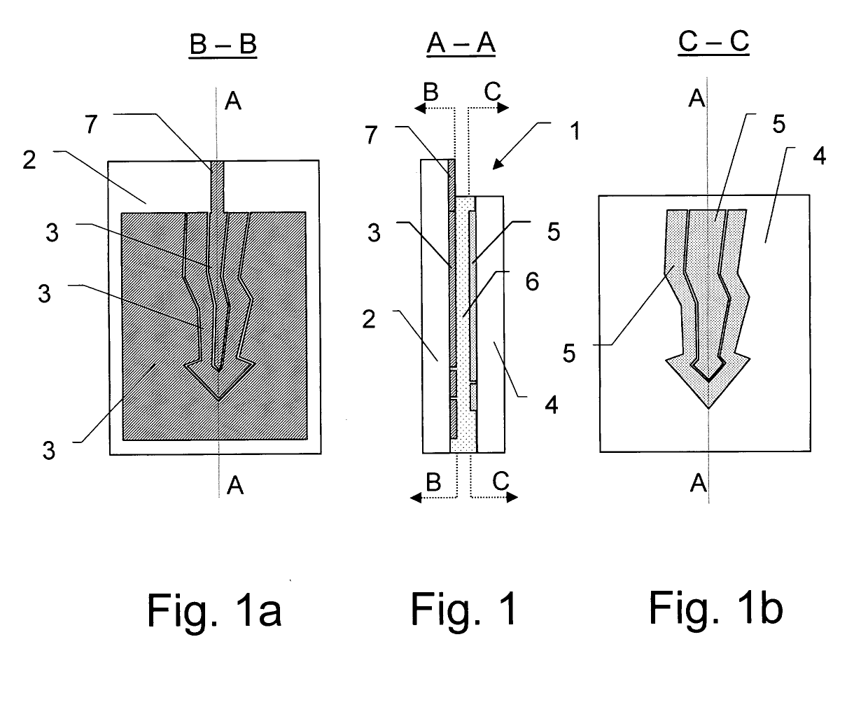

FIGS. 1, 1a and 1b shows the liquid crystal display of the indicator, as a side-section and frontal sections,

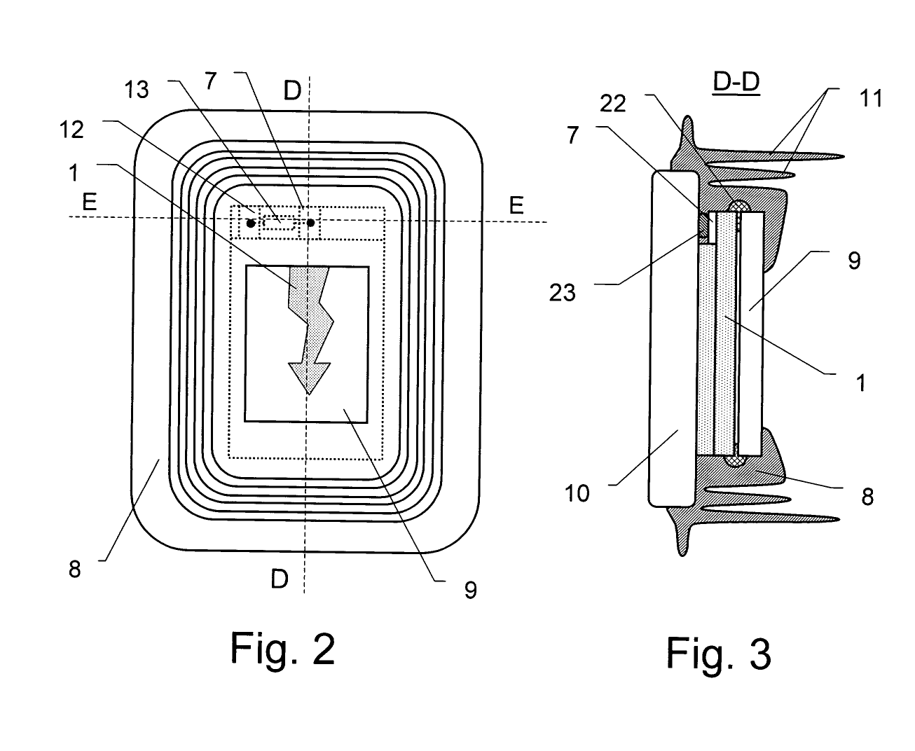

FIG. 2—the front view of the indicator according to the invention,

FIG. 3—a side-section D-D of the indicator according to the invention,

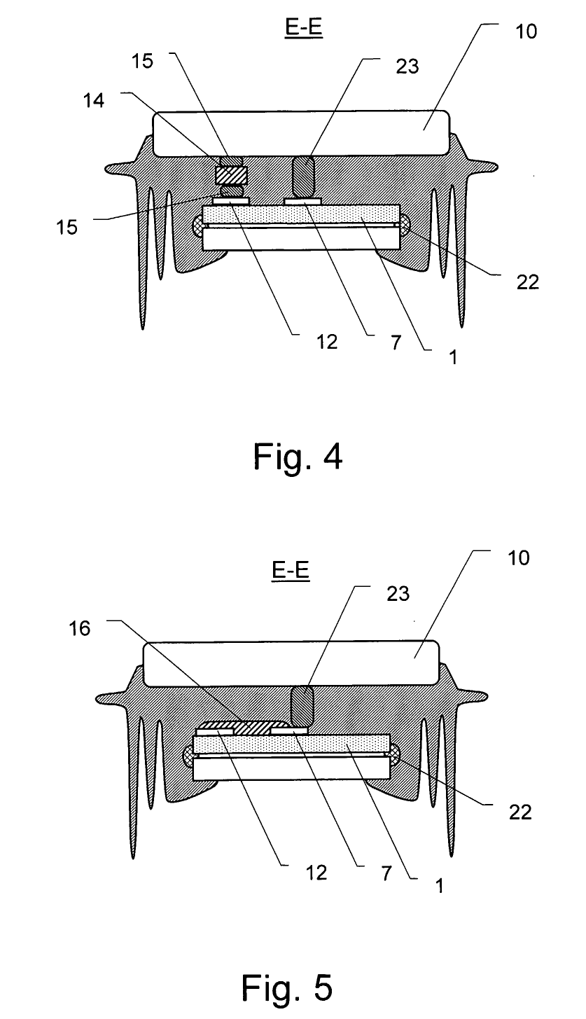

FIGS. 4, 5, 6, 7—various embodiments of the indicator according to the invention in a cross section E-E, and

FIG. 8—an embodiment of the invention comprising a dielectric plate, in a side-section D-D.

The Polish patent application No. P-362 262, filed by the applicant, presents a liquid crystal voltage indicator (FIGS. 1, 1a, 1b), whose LCD 1 comprises the first substrate layer 2 with conducting segments 3 deposited on its surface and electrically insulated from one another, the second substrate layer 4 parallel to the first layer, with conducting segments 5 deposited on its surface and electrically insulated from one another, and an intermediate liquid crystal layer 6 situated between the substrate layers and between the conducting segments. An electric terminal 7 brought out beyond the limits of the surface of the intermediate liquid crystal layer 6 is attached to one of the conducting segments 3. A fragment of each segment located on one substrate layer 2 overlaps with at least one fragment of the segment placed on the second substrate layer 4 and the overlapping fragments of the conducting segments 3, 5 of both substrate layers, together with a part of the intermediate liquid crystal layer 6 form the liquid crystal elements of the indicator, which are electrically connected in series. The liquid crystal elements, on a plane parallel to the substrate layers, constitute together an image of a sign which is displayed in the presence of voltage. The whole area of one of the conducting segments, situated on the plane of one of the substrate layers outside the limits of the sign image, is the current-collecting electrode of the liquid crystal indicator. In the embodiment example it is the segment 3 with the largest surface area.

The indicator according to the invention (FIGS. 2, 3) comprises an LCD 1 which is hermetically placed inside a housing 8 shaped in the form of a frame. The housing 8 is closed on its front by a transparent plate 9, preferably made of glass, which is placed hermetically in the frame window of the housing 8, and the housing 8 is closed on its back by a flat conducting element 10 hermetically placed in the frame of the housing 8. The housing 8 is made of a strongly hydrophobic material, for example of a silicone elastomer, which, after curing, is characterized by a strong and permanently hydrophobic surface, or of a thermoplastic polymer covered by a thin layer of hydrophobic surface properties. The housing 8 is preferably made by overmolding the indicator components connected with one another in layers, i.e. the transparent plate 9, the LCD 1 and the conducting element 10, but the overmolding process does not include the front part of the plate 9 surface and the back surface of the conducting element 10. Instead of overmolding, the housing 8 can be formed by pouring a material with a strongly hydrophobic surface on the finished components of the indicator. On the front part of the housing 8, on the frame window circumference, there are located, at certain spaces between them, circumferential ribs 11 which stand out above the frame window level. The ribs 11 form a uniform whole with the housing 8. The role of the ribs 11 is to increase the path of the current creeping from the conducting element 10 of the indicator to the surface of the plate 9 of the housing 8 frame window, which together with the hydrophobic properties of the surface of the housing 8 allows to increase the total resistance of the indicator surface during its operation in high humidity, rainfall or brine mist.

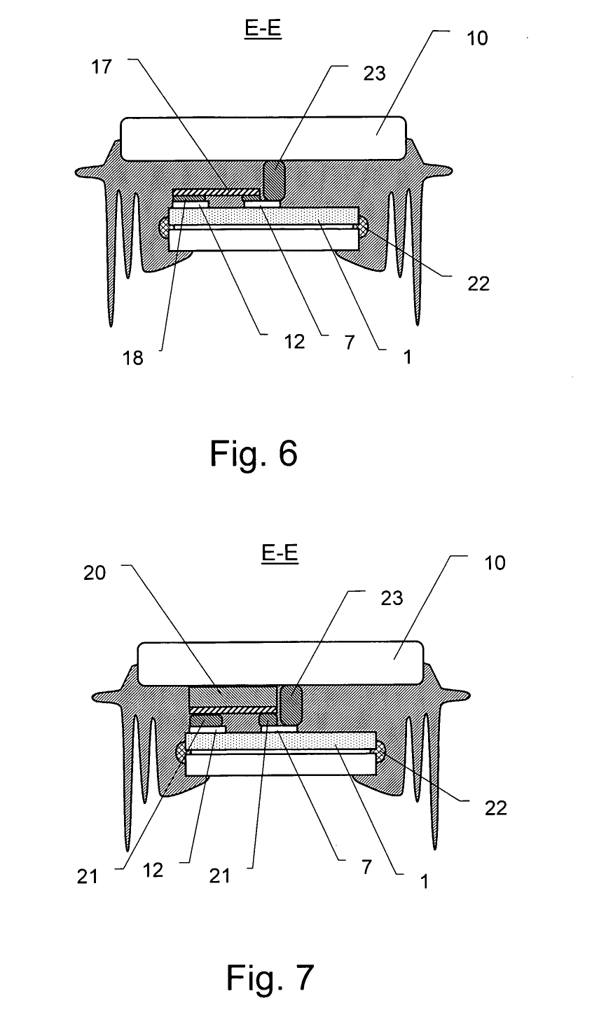

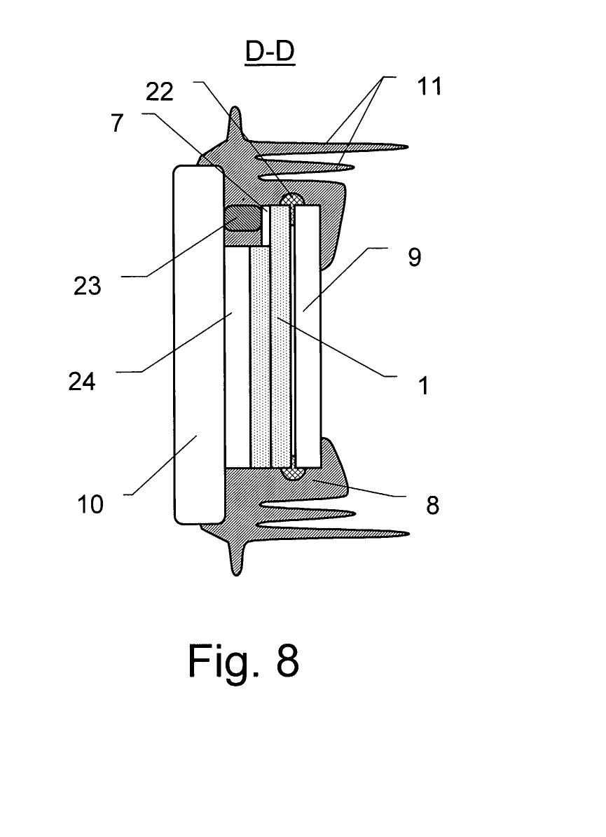

The indicator according to the invention uses a liquid crystal display 1 of a design as shown in FIGS. 1, 1a, 1b, while the conducting segment 3 with the largest surface area, being the current-collecting electrode of the indicator, is provided with a conducting terminal 12. Both terminals 7 and 12 are brought out beyond the limits of the intermediate liquid crystal layer. The liquid crystal elements of the display form an electric series between the segment provided with the terminal 7 and the current-collecting electrode 3 of the indicator. Polarizing plates, not shown in the drawing, adhere to the two substrate layers of the LCD 1, and a light-reflecting film, not shown in the drawing either, adheres to the back polarizing plate. The terminal 7 of the LCD 1 is connected with the terminal 12 by means of a resistive element 13. The purpose of the resistive element 13 is to dampen the DC component of voltage between the terminals 7 and 12 of the LCD 1, generated by static charges accumulating on the indicator. In one of the invention embodiments (FIG. 4) the resistive element 13 is a plate 14 made of antistatic polymer, which is connected with the terminal 12 and the conducting element 10 through connectors 15 made of an electrically conducting silicone elastomer. In another embodiment of the invention (FIG. 5), the resistive element 13 is a layer of resistive paint 16 deposited on one of the substrate layers of the LCD 1 between the terminals 7 and 12. In still another embodiment of the invention (FIG. 6) the resistive element 13 is a layer of resistive material 17 glued to the terminals 7 and 12 with conducting glue 18. In still another embodiment of the invention (FIG. 7) the resistive element 13 is a resistive layer 19 deposited on a ceramic plate 20 and connected with the terminals 7 and 12 by connectors 21. Resistive paper, fabric or foil can also be used as material for making the resistive element.

The LCD 1 is placed hermetically in the housing 8. Between the external substrate layer of the LCD 1 and the internal surface of the transparent plate 9 there is a seal 22 which is positioned along the whole circumference of the connection of the LCD 1 with the transparent plate 9. The purpose of this seal is to prevent pollution of the front surface of the LCD 1 and the back surface of the transparent plate 9 of the housing 8 window during overmolding or pouring-over of the LCD 1 together with the transparent plate 9 and the conducting element 10 by the material of the housing 8. During the operation of the indicator, the seal 22 protects also the front polarizing plate (not shown in the drawing) against excessive penetration of water vapor.

The conducting element 10 is electrically connected with the terminal 7 by means of a conducting connector 23 made of an electrically conducting silicone elastomer. An element (not shown in the drawing) for fixing the indicator to the tested conductor or equipment is attached to the element 10.

The conducting element 10 is made of a thermoplastic polymer with a conducting admixture of carbon particles, conducting polymer or metallic fibers. In another form of the invention embodiment, the conducting element 10 is made of silicone elastomer with a conductive admixture. In still another form of the invention embodiment the conducting element 10 is made of silicone elastomer with a metallic or polymeric core.

In another form of the invention embodiment, shown in FIG. 8, the indicator comprises a dielectric plate 24 placed between the flat conducting element 10 and the LCD 1.

The dielectric plate 24 is made of glass or a thermoplastic polymer, e.g. high-density polyethylene.

1. An indicator of presence of AC voltage comprising a liquid crystal display in an insulating housing, the indications of which display are read in a window in the front wall of the housing, and which liquid crystal display is electrically connected with a conducting element used to couple the liquid crystal display electrodes with the examined object, characterized in that the housing (8) of the indicator has the shape of a frame and is made of a material with strongly hydrophobic surface, which frame on the front side is closed by a transparent plate (9) placed in the window of the housing (8), and on the back side it is closed by a conducting element (10), while at least one row of circumferential ribs (11) is positioned around the frame window, and the liquid crystal display (1) is hermetically placed between the transparent plate (9) of the frame window and the conducting element (10) or it is placed hermetically between the transparent plate (9) of the frame window and a dielectric plate (24) positioned next to the conducting element (10).

2. Indicator according to claim 1, characterized in that, the liquid crystal display (1) has electrodes in the form of conducting segments, where one of the conducting segments (3) with the largest surface area is the current-collecting electrode of the indicator, and to another of the conducting segments (3) there is connected a conducting terminal (12), which is connected to the conducting element (10) of the indicator by means of a connector (23).

3. Indicator according to claim 1 or 2, characterized in that the transparent plate (9) is made of glass.

4. Indicator according to claim 1 or 2, characterized in that the circumferential ribs (11) stand out above the level of the window of the housing (8).

5. Indicator according to claim 1 or 2, characterized in that the housing frame (8) is made of a silicone elastomer with permanently hydrophobic surface.

6. Indicator according to claim 1 or 2, characterized in that the housing frame (8) is made of a thermoplastic polymer coated by a thin layer of hydrophobic surface properties.

7. Indicator according to claim 1 or 2, characterized in that the conducting element (10) is made of thermoplastic polymer with a conducting admixture in the form of carbon particles, conducting polymer or metallic fibers.

8. Indicator according to claim 1 or 2, characterized in that the conducting element (10) is made of a silicone elastomer with a conducting admixture.

9. Indicator according to claim 1 or 2, characterized in that the conducting element (10) is made of a silicone elastomer with a metallic or polymeric core.

10. Indicator according to claim 1 or 2, characterized in that the dielectric plate (24) is made of glass.

11. Indicator according to claim 1 or 2, characterized in that the dielectric plate (24) is made of a thermoplastic polymer.

12. Indicator according to claim 2, characterized in that the conducting terminal (12) is connected through a resistive element (13) to a terminal (7) attached to the current-collecting electrode.

13. Indicator according to claim 12, characterized in that the resistive element (13) is made in the form of a plate (14) of an antistatic polymer, which is connected with the terminal (12) and the conducting element (10) through connectors (15).

14. Indicator according to claim 12, characterized in that the resistive element (13) is deposited on one of the substrate plates of the liquid crystal display (1) between its terminals (7) and (12) in the form of resistive paint (16).

15. Indicator according to claim 12, characterized in that the resistive element (13) is a resistive material layer (17) glued to the terminals (7) and (12) with conducting glue (18).

16. Indicator according to claim 12, characterized in that the resistive element (13) is made of resistive paper, fabric or foil.

17. Indicator according to claim 12, characterized in that the resistive element (13) has the form of a plate with a resistive layer deposited on it.
